(19) United States
(12) Patent Application Publication
(10) Pub. No.: US 2017/0358383 A1
(43) Pub. Date: Dec. 14, 2017

(54) TRANSPARENT CONDUCTIVE FILM

(71) Applicant: NITTO DENKO CORPORATION, Ibaraki-shi, Osaka (JP)

(72) Inventors: Nozomi Fujino, Osaka (JP); Daiki Kato, Osaka (JP); Tomotake Nashiki, Osaka (JP)

(73) Assignee: NITTO DENKO CORPORATION, Ibaraki-shi, Osaka (JP)

(21) Appl. No.: 15/532,678

(22) PCT Filed: Nov. 27, 2015
(86) PCT No.: PCT/JP2015/083339

§ 371 Date: Jun. 2, 2017

(30) Foreign Application Priority Data
Dec. 22, 2014 (JP) 2014-258382
Nov. 16, 2015 (JP) 2015-223724

(51) Int. Cl. H01B 5/14; C23C 14/08; G06F 3/041; C23C 14/10; C23C 14/34

(52) U.S. Cl. CPC H01B 5/14; C23C 14/10; C23C 14/34; G06F 3/041; C23C 14/081

(57) ABSTRACT

A transparent conductive film includes: a transparent film substrate; an optical adjustment layer; and a transparent conductive layer, in which the optical adjustment layer and the transparent conductive layer are laminated on a main surface of the transparent film substrate in this order; The optical adjustment layer includes a dry-type optical adjustment layer including an inorganic oxide. The transparent conductive layer includes a metal oxide including indium. The transparent conductive layer is crystalline and has an X-ray diffraction peak respectively at least on a (400) plane and a (440) plane. When the (400) plane has an X-ray diffraction peak intensity of I₄₀₀ and the (440) plane has an X-ray diffraction peak intensity of I₄₄₀, a ratio I₄₄₀/I₄₀₀ of the X-ray diffraction peak intensity is in a range from 1.0 to 2.2.

### BACKGROUND OF THE INVENTION

### Field of the Invention

The present invention relates to a transparent conductive film.

### Description of the Related Art

A transparent conductive film, in which a transparent conductive layer is formed on one main surface of a transparent film substrate, has conventionally been well-known. Transparent conductive films are widely used for apparatuses such as touch panels. When a transparent conductive film is used for a touch panel, micro wiring patterns are produced by wet etching of the transparent conductive layer. At this time in the case where the etching rate of the transparent conductive layer is too fast, it is impossible to precisely form wiring patterns due to a problem with side etching of the micro wiring. Conversely, when the etching rate of the transparent conductive layer is too slow, productivity of a patterning process decreases. In such a manner, the etching rate of the transparent conductive layer has an appropriate range (for instance, JP 5425351 B).

In a transparent conductive film, technology to form an optical adjustment layer (Index Matching Layer) between a film substrate and a transparent conductive layer and to make wiring patterns of the transparent conductive layer difficult to be seen is known (for instance, JP 2012-114070 A). Generally, a wet-type optical adjustment layer formed by a wetting method and a dry-type adjustment layer formed by a drying method are known as optical adjustment layers. A wet-type optical adjustment layer is, for instance, formed by dissolving a thermosetting resin composed of a mixture of melamine resin and alkyd resin and an organic silane condensate in an organic solvent to be coated to a film substrate and to be hardening treated (for example, heating treatment). On the other hand, a dry-type optical adjustment layer is, for instance, formed by depositing an inorganic oxide such as silicon oxide (SiO₂) and aluminum oxide (Al₂O₃) on a film substrate by a sputtering method or the like.

FIG. 3 shows a schematic view of a conventional transparent conductive film 30. A transparent film substrate 31 and a wet-type optical adjustment layer 32, and a transparent conductive layer 33 are laminated in this order in the transparent conductive film 30.

Since the wet-type optical adjustment layer 32 has a low layer density and a low hardness, the transparent conductive film 30 has such a disadvantage that scratch resistance thereof is low. On the other hand, a dry-type optical adjustment layer (not shown) tends to have a higher layer density and a higher hardness than the wet-type optical adjustment layer 32, resulting in excellent scratch resistance of the transparent conductive film. In recent years, as wiring of a transparent conductive layer becomes finer, a risk for disconnection of wiring becomes higher even in the case of minor scratches. As a result, cases where a dry-type optical adjustment layer having high scratch resistance is adopted have been increasing instead of the wet-type optical adjustment layer 32 having low scratch resistance.

When a transparent conductive layer is formed on a wet-type optical adjustment layer, it is possible to etch the transparent conductive layer at a suitable rate. However, when a transparent conductive layer is formed on a dry-type optical adjustment layer, the etching rate of the transparent conductive layer becomes slower. As a result, there are fears that productivity in a patterning process may be lowered. That is, the wet-type optical adjustment layer is excellent from the viewpoint of etching property of the transparent conductive layer. However, the dry-type optical adjustment layer is excellent from the viewpoint of scratch resistance. Conventionally, transparent conductive films each having a dry-type optical adjustment layer with high scratch resistance and each having an appropriate etching rate of a transparent conductive layer have not been known.

### PRIOR ART DOCUMENTS

### Patent Documents

Patent Document 1: JP 5425351 B

Patent Document 2: JP 2012-114070 A

### SUMMARY OF THE INVENTION

It is an object of the present invention to realize a transparent conductive film having an optical adjustment layer including a dry-type optical adjustment layer and an appropriate etching rate of a transparent conductive layer from a viewpoint of scratch resistance.

As a result of extensive study of the inventors of the present invention, the present invention has been accomplished by finding that it is possible to control the etching rate of a transparent conductive layer in an appropriate range by properly controlling crystalline orientation of the transparent conductive layer even when an optical adjustment layer includes a dry-type optical adjustment layer.

The summary of the present invention is described as below.

In a first preferred aspect, there is provided a transparent conductive film according to the present invention which includes: a transparent film substrate; an optical adjustment layer; and a transparent conductive layer, at least the optical adjustment layer and the transparent conductive layer being laminated on at least one main surface of the transparent film substrate. The optical adjustment layer includes a dry-type optical adjustment layer including an inorganic oxide. The transparent conductive layer includes a metal oxide including indium. The transparent conductive layer is crystalline and has an X-ray diffraction peak respectively at least on a (400) plane and a (440) plane. When the (400) plane has an X-ray diffraction peak intensity of I₄₀₀ and the (440) plane has an X-ray diffraction peak intensity of I₄₄₀, a ratio I₄₄₀/I₄₀₀ of the X-ray diffraction peak intensity is in a range from 1.0 to 2.2.

In a second preferred aspect, there is further provided a transparent conductive film according to the present invention which includes: a transparent film substrate; an optical adjustment layer; and a transparent conductive layer, at least the optical adjustment layer and the transparent conductive layer being laminated on at least one main surface of the transparent film substrate. The optical adjustment layer includes a dry-type optical adjustment layer including an inorganic oxide. The transparent conductive layer includes a metal oxide including indium. The transparent conductive layer is crystalline and has an X-ray diffraction peak respectively at least on a (222) plane, a (400) plane, and a (440) plane. When the (222) plane has an X-ray diffraction peak intensity of I₂₂₂, the (400) plane has an X-ray diffraction peak intensity of I₄₀₀ and the (440) plane has an X-ray diffraction peak of I₄₄₀, a ratio I₄₀₀/I₂₂₂ of the X-ray diffraction peak intensity is in a range from 0.10 to 0.26 and a ratio I₄₄₀/I₄₀₀ of the X-ray diffraction peak intensity is in a range from 1.0 to 2.2.

In a third preferred aspect of the transparent conductive film according to the present invention, the dry-type optical adjustment layer includes an area of an inorganic oxide having a carbon atom content of 0.2 atomic % or lower in a thickness direction.

In a fourth preferred aspect of the transparent conductive film according to the present invention, the transparent conductive layer is a transparent conductive thin layer laminate composed of at least two layers of transparent conductive thin layers. All of the transparent conductive thin layers include at least one kind of impurity metallic element except indium. When a transparent conductive thin layer located at a position that is the farthest from the film substrate is a first transparent conductive thin layer, the content ratio of impurity metallic element relative to indium in the first transparent conductive thin layer is not the maximum out of content ratios of impurity metallic element relative to indium in all of the transparent conductive thin layers that constitute the transparent conductive thin layer laminate. For instance, when the transparent conductive layer includes a second transparent conductive thin layer and the first transparent conductive thin layer from a film substrate side, the content ratio of impurity metallic element relative to indium of the first transparent conductive thin layer is lower than the content ratio of impurity metallic element relative to indium of the second transparent conductive thin layer.

In addition, “the content ratio of impurity metallic element relative to indium” is represented by a ratio [N_{D}/N_{P}] of atom number N_{D} of impurity metallic element relative to atom number N_{P} of indium element in the transparent conductive layer. For instance, the content ratio of tin relative to indium in an indium tin oxide is represented by a ratio [N_{Sn}/N_{In}] of the atom number N_{Sn} of tin atom relative to atom number N_{In} of indium element in the transparent conductive thin layer.

In a fifth preferred aspect of the transparent conductive film according to the present invention, the content ratio of impurity metallic element relative to indium in the first transparent conductive thin layer is the lowest out of content ratios of impurity metallic element relative to indium in all of the transparent conductive thin layers that constitute the transparent conductive thin layer laminate.

In a sixth preferred aspect of the transparent conductive film according to the present invention, the content ratio of impurity metallic element relative to indium in the first transparent conductive thin layer is 0.004 or more to less than 0.05.

In a seventh preferred aspect of the transparent conductive film according to the present invention, a content ratio of impurity metallic element relative to indium in each transparent conductive thin layer except the first transparent conductive thin layer out of all of the transparent conductive thin layers that constitute the transparent conductive thin layer laminate is 0.05 or more to 0.16 or less.

In an eighth preferred aspect of the transparent conductive film according to the present invention, the first transparent conductive thin layer has a thickness thinner than the thickness of all of the transparent conductive thin layers except the first transparent conductive thin layer in the at least two layers of transparent conductive thin layers that constitute the transparent conductive thin layer laminate.

In a ninth preferred aspect of the transparent conductive film according to the present invention, the impurity metallic element is composed of tin (Sn).

According to the present invention, a transparent conductive film which has a suitable etching rate of a transparent conductive layer while an optical adjustment layer includes a dry-type optical adjustment layer having a high scratch resistance, more specifically, a transparent conductive film having both scratch resistance and etching property has been materialized.

### BRIEF DESCRIPTION OF THE DRAWINGS

FIG. 1 is a schematic view of a first embodiment of a transparent conductive film of the present invention;

FIG. 2 is a schematic view of a second embodiment of a transparent conductive film of the present invention;

FIG. 3 is a schematic view of a conventional transparent conductive film; and

FIG. 4 is one example of a profile of the Electron Spectroscopy for Chemical Analysis (ESCA).

### DESCRIPTION OF THE PREFERRED EMBODIMENTS

### Transparent Conductive Film: First Embodiment

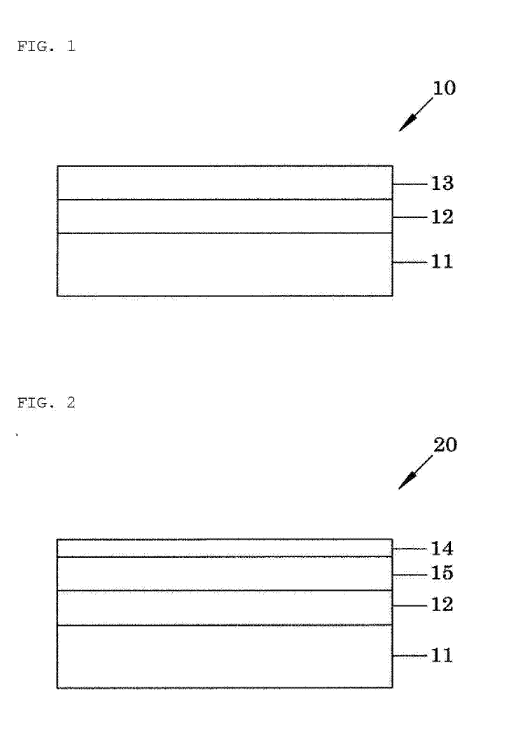

FIG. 1 shows a schematic view of a transparent conductive film 10 according to a first embodiment of the present invention. The transparent conductive film 10 includes: a transparent film substrate 11; an optical adjustment layer 12; and a transparent conductive layer 13, which are laminated in this order. The optical adjustment layer 12 includes an inorganic oxide layer (a dry-type optical adjustment layer) formed by a dry-type deposition method. The transparent conductive layer 13 includes a metal oxide including indium. The transparent conductive layer 13 is crystalline and includes a crystalline structure having an X-ray diffraction peak which corresponds to at least a (400) plane and a (440) plane. When the X-ray diffraction peak intensity of the (400) plane is I₄₀₀ and the X-ray diffraction peak intensity of the (440) plane is I₄₄₀, the ratio I₄₄₀/I₄₀₀ of the X-ray diffraction peak intensity is in a range from 1.0 to 2.2.

More preferably, the transparent conductive layer 13 further includes a crystalline structure having an X-ray diffraction peak which corresponds to a plane (222). When the X-ray diffraction peak intensity of the plane (222) is I₂₂₂, the ratio I₄₀₀/I₂₂₂ of the X-ray diffraction peak intensity is in a range from 0.10 to 0.26.

### [Film Substrate]

The film substrate is typically made from a polymer film such as polyethylene terephthalate, polyethylene naphthalate, polyolefin, polycyclo olefin, polycarbonate, polyethersulfone, polyallylate, polyimide, polyamide, polystylene, and norbornene. While the material of the film substrate is not limited, polyethylene terephthalate (PET) which is superior in transparency, heat resistance, and mechanical property is particularly preferable.

While the film substrate preferably has a thickness of 20 μm or more to 300 μm or less, the thickness of the film substrate is not limited to this. In the case where the thickness of the film substrate is less than 20 μm, there are fears that it may be difficult to handle the film substrate. In the case where the thickness of the film substrate is over 30 μm, the transparent conductive film becomes too thick when mounted on a touch panel or the like, which may cause a problem.

While it is not shown, a functional layer such as an easily adhering layer, an undercoat layer, an anti-blocking layer, an oligomer blocking layer or a hard coat layer may be provided on a surface of a transparent conductive layer-side and a surface on the opposite side thereof of the film substrate when necessary. The easily adhering layer has the function of increasing adhesion between the film substrate and a layer formed on the film substrate (for instance, an optical adjustment layer). The undercoat layer has the function of adjusting a reflectance and an optical hue of the film substrate. The anti-blocking layer has the function of suppressing blocking caused by winding of the transparent conductive film. The oligomer blocking layer has the function of suppressing a low molecular weight component deposited when heating the film substrate (for instance, PET film substrate). The hard coat layer has the function of increasing scratch resistance of the transparent conductive film. The functional layer is preferably composed of a composition including an organic resin.

### [Optical Adjustment Layer]

An optical adjustment layer is a layer for adjusting a refractive index arranged between the film substrate and the transparent conductive layer. It is possible to optimize optical characteristics (for instance, reflection characteristics) of the transparent conductive film by providing an optical adjustment layer. Since the optical adjustment layer makes the difference between a portion having wiring patterns and a portion without wiring patterns in the transparent conductive layer smaller, the wiring patterns of the transparent conductive layer become difficult to be visible (it is not preferable that the wiring patterns of the transparent conductive layer is visible).

The optical adjustment layer includes a dry-type optical adjustment layer (not shown) composed of a dry-type deposition layer deposited by the dry-type deposition method such as a sputtering method, a vacuum deposition method, and a Chemical Vapor Deposition method. The dry-type optical adjustment layer includes an inorganic oxide layer and is preferably composed of an inorganic oxide layer. In addition, a production method for a dry-type optical adjustment layer is not limited as long as the production method is a dry-type deposition method which enables to obtain sufficient scratch resistance and the production method is not limited to the sputtering method, the vacuum deposition method, and the chemical vapor deposition method. Vacuum deposition, sputtering, and ion-plating may be referred to as “physical deposition,” CVD may be referred to as “chemical deposition,” and “physical deposition” and “chemical deposition” may be referred together to simply as “deposition.” Using this terminology, the phrase “a dry-type optical adjustment layer including an inorganic oxide deposited by the dry-type deposition method” is described as “a dry-type optical adjustment layer composed of a deposition layer including an inorganic oxide.”

The optical adjustment layer may be a multi-layered structure composed of a wet-type optical adjustment layer and a dry-type optical adjustment layer. The optical adjustment layer including a dry-type optical adjustment layer includes a layer (a dry-type optical adjustment layer) having a high hardness, resulting in high scratch resistance of the transparent conductive film. Additionally, since the optical adjustment layer includes a dry-type adjustment layer including an inorganic oxide layer, the optical adjustment layer has gas barrier property. This makes it possible to prevent deterioration of the layer of the transparent conductive layer caused by gas (for instance, moisture) generated from the film substrate.

When the optical adjustment layer is a multi-layered structure of a wet-type optical adjustment layer and a dry-type optical adjustment layer, the dry-type optical adjustment layer is preferably formed on the wet-type optical adjustment layer (the transparent conductive layer-side). The wet-type optical adjustment layer may contain a great amount of gas (for instance, gas caused by an organic solvent) and this may cause deterioration of layer of the transparent conductive layer. It is possible to surely suppress deterioration of layer of the transparent conductive layer caused by gas generated from the film substrate and gas generated from the wet-type optical adjustment layer by forming the dry-type optical adjustment layer having gas barrier property on the wet-type optical adjustment layer.

When the optical adjustment layer is multi-layered structured composed of a wet-type optical adjustment layer and a dry-type optical adjustment layer, the dry-type optical adjustment layer is formed on the wet-type optical adjustment layer and the dry-type optical adjustment layer is formed adjacent to the transparent conductive layer. This structure makes it possible to suppress deterioration of the layer quality of the transparent conductive layer caused by gas and in addition, it is possible to surely improve scratch resistance by the formation of the dry-type optical adjustment layer having a high hardness immediately below the transparent conductive layer.

While the component material of the dry-type optical adjustment layer is not particularly limited, for instance, the component material is an inorganic oxide such as silicon oxide (silicon monoxide (SiO), silicon dioxide (SiO₂)) (it is generally called as a silicon oxide), silicon suboxide (SiOx: x is over 1 and less than 2), aluminum oxide (Al₂O₃), zirconium oxide (ZrO₂), niobium oxide (Nb₂O₅), titanium dioxide (TiO₂). The composition of the inorganic oxide may be stoichiometric composition or non-stoichiometric composition. The dry-type optical adjustment layer may be a composite layer where an inorganic oxide layer of stoichiometric composition and an inorganic oxide layer of non-stoichiometric composition are laminated.

Even when the dry-type optical adjustment layer is a single layered inorganic oxide layer, the dry-type optical adjustment layer may be a laminate of an inorganic oxide layer where a plurality of inorganic oxide layers each having different inorganic elements are laminated. The optical adjustment layer including a dry-type optical adjustment layer has a higher scratch resistance than a wet-type optical adjustment layer. As a result, the optical adjustment layer has higher scratch resistance of the transparent conductive layer than the optical adjustment layer excluding a dry-type optical adjustment layer. The dry-type optical adjustment layer is preferably laminated adjacent to the transparent conductive layer. Laminating the dry-type optical adjustment layer adjacent to the transparent conductive layer makes the dry-type optical adjustment layer having a high hardness have a structure configured to directly support the transparent conductive layer, which leads to a higher scratch resistance of the transparent conductive layer.

While the thickness of the optical adjustment layer is not necessarily limited, for instance, the optical adjustment layer has a thickness of 2 nm or more, preferably 5 nm or more, more preferably 10 nm or more, and e.g. 100 nm or less, preferably 80 nm or less, more preferably 60 nm or less. When the optical adjustment layer has a thickness of less than 2 nm, there may be a case where scratch resistance is insufficient. When the optical adjustment has a thickness of over 100 nm, there are fears that flexibility resistance of the transparent conductive film may become deteriorated.

While the deposition method of the inorganic oxide layer is not necessarily limited, it is preferable to deposit the inorganic oxide layer by the sputtering method.

Even in a drying process, in general, it is possible to stably obtain a particularly dense layer in a sputtering layer formed by the sputtering method. Accordingly, the optical adjustment layer including the inorganic oxide layer formed by the sputtering method has a higher scratch resistance than, for instance, the optical adjustment layer formed by the vacuum deposition method. Further, in general, the layer to be formed has a density higher in the sputtering method than the vacuum deposition method, for instance, which makes it possible to obtain a layer superior in gas barrier property. The higher the layer density of the inorganic oxide layer is, more preferable it would be. For instance, in the case where the inorganic oxide layer is composed of silicon dioxide (SiO₂), to surely obtain scratch resistance and gas barrier property, the inorganic oxide layer preferably has a layer density of 2.1 g/cm³ or more. It is possible to obtain a layer density of the inorganic oxide layer by an X-ray reflectance method.

While pressure of sputtering gas at the time when the inorganic oxide layer is deposited is not limited, for instance, the pressure is preferably 0.09 Pa to 0.5 Pa, more preferably 0.09 Pa to 0.3 Pa. It is possible to form a denser sputtering layer by making the pressure of the sputtering gas in the aforementioned range. As a result, it becomes easy to obtain preferable scratch resistance and gas barrier property. When the pressure of the sputtering gas is over 0.5 Pa, there are fears that it may be impossible to obtain a dense layer. When the pressure of the sputtering gas is less than 0.09 Pa, discharging becomes unstable, which may result in formation of voids on the inorganic oxide layer.

When an inorganic oxide layer is deposited by the sputtering method, effective deposition is possible by use of a reactive sputtering method. For instance, it is possible to obtain a silicon oxide (e.g. silicon dioxide (SiO₂)) layer having high scratch resistance and gas barrier property by use of silicon (Si) as a sputtering target, introducing argon as a sputtering gas, and oxygen as a reactive gas (the introduction amount is e.g. 10% by volume to 80% by volume).

When the optical adjustment layer includes a dry-type optical adjustment layer, particularly, when the dry-type optical adjustment layer is formed adjacent to the transparent conductive layer, although the reason why the etching rate of the transparent conductive layer is delayed is not limited to any theories, an assumption is made as below. When the optical adjustment layer is composed of a wet-type optical adjustment layer, even in the case where the transparent conductive layer is heating crystallization treated (e.g. 140° C., for 60 minutes), the area of the film substrate-side of the transparent conductive layer (for instance, the area of a thickness of about 3 nm adjacent to the wet-type optical adjustment layer) does not easily have a stable crystalline structure due to gas derived from the film substrate and the wet-type optical adjustment layer, resulting in a structure relatively close to be amorphous.

Compared between the crystalline etching rate and the amorphous etching rate, the amorphous etching rate is extremely fast. As a result, it is presumed that the etching rate of the transparent conductive layer becomes faster from a surface side (a side opposite to the film substrate) toward the film substrate-side. On the other hand, when the optical adjustment layer includes a dry-type optical adjustment layer, the dry-type optical adjustment layer has gas barrier property and therefore, the optical adjustment layer is not subjected to gas derived from the film substrate. Accordingly, a uniform crystalline material over the entire thickness direction in the transparent conductive layer is obtained. As a result, the etching rate in the thickness direction of the transparent conductive layer has no changes and consequently, it is presumed that the etching rate becomes slower.

In the present invention, the dry-type optical adjustment layer that constitutes the optical adjustment layer preferably has an area which does not substantially include an inorganic atom (e.g. silicon atom) and impurity atoms (e.g. carbon atom) other than an oxygen atom that constitute an inorganic oxide (e.g. silicon dioxide) in the thickness direction. More concretely, the carbon atom preferably has an area of 0.2 atomic % or less in the thickness direction (in the present invention, for the aforementioned reason, when the carbon atom is 0.2 atomic % or less, the carbon atom is not substantially included in the area).

When the dry-type optical adjustment layer includes a carbon atom, the carbon atom is derived from a film substrate or a wet-type hard coat layer formed on the film substrate by a wet method. In addition, there is a case where the wet-type optical adjustment layer includes a carbon atom derived from an organic resin.

In this specification, whether there is an area having a carbon atom of 0.2 atomic % or lower is decided by performing a depth profile measurement by use of ESCA: Electron Spectroscopy for Chemical Analysis.

Carbon atom decreases the layer density of the dry-type optical adjustment layer and causes a decrease in scratch resistance of the transparent conductive film. The optical adjustment layer has an area having a carbon atom of 0.2 atomic % or lower (which does not substantially include a carbon atom) in a thickness direction, which makes it possible to obtain sufficient scratch resistance of the transparent conductive film.

Although it is preferable that the content of the carbon atom contained in the dry-type optical adjustment layer is lesser. However, when the content of the carbon atom is 0.2 atomic % or lower in the Electron Spectroscopy for Chemical Analysis, the content of the carbon atom becomes below standards of the limit of a device detection, which may result in impossibility of detection of the carbon atom. Accordingly, it is judged that a carbon atom is not substantially included when the content of the carbon atom is 0.2 atomic % or lower in the present invention.

When a ratio of the total thicknesses of the dry-type optical adjustment layer is 100%, the ratio of a thickness direction in an area having a carbon atom content of 0.2 atomic % or lower is e.g. 10% or higher, preferably 15% or higher, more preferably 20% or higher, further preferably 25% or higher, the most preferably 30% or higher. “The area having a carbon atom content of 0.2 atomic % or lower” is obtained by the ESCA and the details thereof is described in the column of “content of carbon atom of optical adjustment layer and evaluation of an existence area.” The ratio of the thickness direction in an area having a carbon atom content of 0.2 atomic % or lower is obtained by obtaining a thickness A (nm) of the dry-type optical adjustment layer and a thickness B (nm) of the area where carbon atom is detected in the dry-type optical adjustment layer and calculating an equation “100−(B/A)×100 (unit: %).” When the ratio of the thickness direction of the area having a carbon atom is 10% or higher, it is possible to obtain sufficient scratch resistance. Higher the ratio of the thickness of the area having a carbon atom content of 0.2 atomic % or lower, the better the ratio is higher. There is, however, a limit in analysis and it is impossible to obtain an analysis of 100% because a carbon atom that constitutes the film substrate of the optical adjustment layer is detected near the film substrate. The upper limit value of the ratio of the thickness direction of the area having a carton atom content is e.g. 90%.

To obtain a dry-type optical adjustment layer which does not include impurity atoms (e.g. carbon atom), it is preferable to deposit a dry-type optical adjustment layer in a state in which the film substrate is not excessively heated. For instance, it is preferable to deposit a dry-type optical adjustment layer while cooling a surface opposite to the side at which the optical adjustment layer of the film substrate is deposited at −20° C. to +15° C. Discharge of gas component contained in the film substrate is suppressed by depositing the film substrate in a state in which the film substrate is being cooled. This enables to prevent the dry-type optical adjustment layer from including impurity atoms (e.g. carbon atom), which makes it easy to obtain the dry-type optical adjustment layer having a high layer density.

### [Transparent Conductive Layer]

A transparent conductive layer includes a layer including a metal oxide which contains indium, that is, a transparent thin layer essentially composed of indium oxide or a transparent thin layer essentially composed of composite metal oxide containing at least one kind of impurity metallic element. In the case where the transparent conductive layer includes a layer which contains indium and has optical transparency in a visible region and conductivity, there is no possibility of the components being particularly limited. Further, the transparent conductive layer is preferably composed of metal oxide containing indium.

While indium oxide, indium tin oxide (ITO) and indium gallium zinc oxide (IGZO) or the like are typically used as a material for a transparent conductive layer, indium tin oxide (ITO) is preferable from a view point of low resistivity and transmission hue.

At least one kind of impurity metallic element included in the transparent conductive layer is e.g. tin (Sn) in the case of indium tin oxide, gallium (Ga) and zinc (Zn) in the case of indium gallium zinc oxide (IGZO). The transparent conductive layer may further include an impurity metallic element such as titanium (Ti), magnesium (Mg), aluminum (Al), gold (Au), silver (Ag) or copper (Cu). While the transparent conductive layer is formed on an optical adjustment layer by use of the sputtering method, the deposition method, a method for producing the transparent conductive layer is not limited to this.

While the transparent conductive layer may appropriately have a content ratio of impurity metallic element relative to indium in a range from 0.004 or more to 0.16 or less when the transparent conductive layer contains at least one kind of impurity metallic element except indium, such as indium tin oxide (ITO), the content ratio is preferably 0.03 or more to 0.15 or less, more preferably 0.09 or more to 0.13 or less. In the case where the transparent conductive layer has a content ratio of impurity metallic element of less than 0.004, there may be a remarkable increase in a surface resistance value of the transparent conductive layer 13. In the case of over 0.16 of the surface resistance value, uniformity of the surface resistance value in the surface of the transparent conductive layer may be lost.

When an indium tin oxide (ITO) is used as a transparent conductive layer, that is, when the main metal is indium and the impurity metallic element is tin, the content ratio of the impurity metallic element relative to indium is approximately 0.5 weight % or more to 15 weight % or less, 3 weight % or more to 15 weight % or less, 9 weight % or more to 12.5 weight % or less respectively, when expressed by a content ratio of tin oxide (a percentage of the weight of SnO₂ relative to the total weight of In₂O₃ and SnO₂).

“The content ratio of impurity metal oxide” in the present invention is referred to as a weight ratio of impurity metal oxide relative to the total weight of an indium oxide and an impurity metal oxide (a percentage), more specifically, {Weight of SnO₂/(Weight of In₂O₃+weight of SnO₂)}×100(%).

The transparent conductive layer (e.g. indium tin oxide (ITO) layer) formed at a low temperature is amorphous and can be converted from amorphous into crystalline by heat treatment. The transparent conductive layer has a lower surface resistance value by being converted into crystalline. Conditions of the transparent conductive layer at the time of conversion into being crystalline are preferably, for instance, at a temperature of 140° C. and for 90 minutes or shorter from a viewpoint of productivity.

It is possible to confirm whether the transparent conductive layer is crystalline by performing surface transmission Electron Microscope (TEM) observation with a TEM: transmission Electron Microscope. In the case where the transparent conductive layer is formed of an indium tin oxide (ITO), it may be possible to judge whether or not the transparent conductive layer is crystalline by washing with water and measuring resistance between two terminals with 15 mm after immersing the transparent conductive layer in hydrochloric acid (concentration of 5 weight %) at 20° C. for 15 minutes. Since an amorphous indium tin oxide (ITO) layer is etched with hydrochloric acid to be lost, immersion in hydrochloric acid increases resistance. In this specification, when resistance between two terminals having a space of 15 mm is not more than 10 kΩ, the ITO layer is crystalline.

In the transparent conductive film, the transparent conductive layer is crystalline and has at least an X-ray diffraction peak corresponding to (400) and (440) planes. When an X-ray diffraction peak intensity of a (400) plane of the transparent conductive layer is I₄₀₀ arid an X-ray diffraction peak intensity of a (440) plane is I₄₄₀, a ratio I₄₄₀/I₄₀₀ of the X-ray diffraction peak intensity is e.g. 1.0 or more, preferably 1.1 or more, more preferably 1.2 or more and is e.g. 2.2 or less, preferably 2.0 or less, more preferably 1.9 or less, further preferably 1.8 or less. The ratio I₄₄₀/I₄₀₀ of the X-ray diffraction peak intensity of the transparent conductive layer is in the aforementioned range, more specifically, in a range from 1.0 to 2.2, regardless of inclusion of a dry-type optical adjustment layer in the optical adjustment layer, it is possible to control the etching rate of the transparent conductive layer in a suitable range.

In addition to an X-ray diffraction peak corresponding to the (400) and (440) planes, the transparent conductive layer preferably has an X-ray diffraction peak corresponding to a (222) plane. When the X-ray diffraction peak intensity on the (222) plane is I₂₂₂, a ratio I₄₀₀/I₂₂₂ of the X-ray diffraction peak intensity is e.g. 0.10 or more, preferably 0.11 or more, more preferably 0.12 or more, and e.g. 0.26 or less, preferably 0.25 or less, more preferably 0.24 or less, furthermore preferably 0.22 or less, the most preferably 0.21 or less. When the ratio I₄₀₀/I₂₂₂ of the X-ray diffraction peak intensity of the transparent conductive layer is in the aforementioned range, i.e. in a range from 0.10 to 0.26, the etching rate of the transparent conductive layer can be controlled in a suitable range.

In the transparent conductive film, the transparent conductive layer h as a ratio I₄₄₀/I₄₀₀ of the X-ray diffraction peak intensity in a range from 1.0 to 2.2 and the transparent conductive layer has a ratio I₄₀₀/I₂₂₂ of the X-ray diffraction peak intensity in a range from 0.10 to 0.26. When the ratio of the X-ray diffraction peak intensity is in the aforementioned range, it is possible to control the etching rate of the transparent conductive layer in a further suitable range. A value deducing a background is used as each of the X-ray diffraction peak intensities in the present invention.

The reason why the etching rate of the transparent conductive film is controlled in the suitable range by the fact that the ratio (I₄₀₀/I₂₂₂ and I₄₄₀/I₄₀₀) of the X-ray diffraction peak intensity is in the aforementioned range is not limited to any theory. The reason is, however, presumed as mentioned below. There is a case where the transparent conductive layer has a different etching rate according to crystalline orientation thereof. Accordingly, when the transparent conductive layer is polycrystalline-oriented such as an indium tin oxide layer (ITO), it is assumed that the etching rate can be adjusted to a suitable range by controlling the crystalline orientation thereof.

Particularly, in the case where the optical adjustment layer includes a dry-type optical adjustment layer, as mentioned above, the optical adjustment layer is not subjected to gas derived from the film substrate. Accordingly, a uniform crystalline material over the entire thickness direction in the transparent conductive layer is obtained. As a result, crystalline oriented factors particularly greatly impact the etching rate. On the other hand, in the case where the optical adjustment layer is composed of a wet-type optical adjustment layer, the optical adjustment layer is subjected to gas of the film substrate and the wet-type optical adjustment layer. Accordingly, a portion of the film substrate of the transparent conductive layer becomes similar to an amorphous layer, which is easily etched on a portion of the film substrate side of the transparent conductive layer, so that impact of factors of the layer feature at the film substrate side is more than factors having crystalline orientation. As a result, it is presumed that a preferable etching rate can stably be obtained.

A method for adjusting intensity of an X-ray diffraction peak of the transparent conductive layer is not particularly limited. For instance, it is possible to adjust the intensity of an X-ray diffraction peak that corresponds to the (400) plane, the (440) plane or the (222) plane to a preferable level by appropriately changing production conditions of the transparent conductive layer (e.g. film forming pressure or substrate temperature at the time of film formation), the layer composition of the transparent conductive layer (e.g. kinds and content ratios of impurity metallic elements), and the layer thickness or the layer configuration (e.g. lamination of transparent conductive layers each having a different content ratio of impurity metallic element). For instance, the substrate temperature at the time of film formation is preferably −40° C. or higher to 180° C. or lower, more preferably −30° C. or higher to 140° C. or lower. When the substrate temperature is under −40° C., the transparent conductive layer becomes difficult to be crystalline and when the substrate temperature is over 180° C., there are fears that it may be impossible to adjust the intensity ratio (I₄₀₀/I₂₂₂ and I₄₄₀/I₄₀₀) of the X-ray diffraction peak of the transparent conductive layer to a preferable level. Further, in this specification, “the substrate temperature at the time of film formation” is a setting temperature of the base of the substrate at the time of sputtering deposition. For instance, the substrate temperature in the case where sputtering deposition is continuously performed by a roll sputtering apparatus is a temperature of film forming roll at which sputtering deposition is performed.

The transparent conductive layer preferably has an arithmetic surface roughness Ra of not less than 0.1 nm and not more than 2.0 nm, more preferably not less than 0.1 nm and not more than 1.5 nm. When the arithmetic surface roughness Ra is over 2.0 nm, there is a possibility that the resistance value of the transparent conductive layer may significantly increase. When the arithmetic surface roughness Ra is less than 0.1 nm, there is a possibility that etching failure may occur due to decrease in adhesion of a photoresist and the transparent conductive layer when patterning wiring is formed on the transparent conductive layer by photolithography.

The transparent conductive layer has a specific resistance value of e.g. 4×10⁻⁴ Ω·cm or less, preferably 3.8×10⁻⁴ Ω·cm or less, more preferably 3.3×10⁻⁴ Ω·cm or less, furthermore preferably 3.0×10⁻⁴ Ω·cm or less, further preferably 2.7×10⁻⁴ Ω·cm or less, the most preferably 2.4×10⁻⁴ Ω·cm or less and more specifically, 1×10⁻⁴ Ω·cm or more. It is possible to preferably use the transparent conductive layer as a transparent electrode for a large touch panel by making the specific resistance value of the transparent conductive layer lower.

The transparent conductive layer having a low specific resistance value tends to have a large crystalline grain size and a slow etching rate. In addition, the tendency is particularly prominent in a transparent conductive layer having a low specific resistance formed on a dry-type optical adjustment layer. The transparent conductive film of the present invention, however, controls crystalline orientation of the transparent conductive layer to adjust the intensity of the X-ray diffraction peak that corresponds to the (400) plane, the (440) plane or the (222) plane. This makes it possible to preferably adopt a transparent conductive layer with a low specific resistance value.

In accordance with the JIS K7194 (in 1994), it is possible to obtain a specific resistance value of the transparent conductive layer by using a surface resistance value (Ω/square) of the transparent conductive layer measured by a four terminal method and a thickness of the transparent conductive layer measured by a transmission electron microscope.

The transparent conductive layer preferably has an arithmetic surface roughness Ra of not less than 0.1 nm and not more than 2.0 nm, more preferably not less than 0.1 nm and not more than 1.5 nm. When the arithmetic surface roughness Ra is over 2.0 nm, there is a possibility that the resistance value of the transparent conductive layer may significantly increase. When the arithmetic surface roughness Ra is less than 0.1 nm, there is a possibility that etching failure may occur due to decrease in adhesion of a photoresist and the transparent conductive layer when patterning wiring is formed on the transparent conductive layer by photolithography.

### [Transparent Conductive Film: Second Embodiment]

FIG. 2 shows a schematic view of a transparent conductive film 20 of a second embodiment according to the present invention (Same reference numerals are used for common elements to the configuration of FIG. 1). In a transparent conductive film 20, at least a transparent film substrate 11, an optical adjustment layer 12, a second transparent conductive thin layer 15, and a first transparent conductive thin layer 14 are laminated in this order. A transparent conductive layer is composed of the first transparent conductive thin layer 14 and the second transparent conductive thin layer 15. The first transparent conductive thin layer 14 and the second transparent conductive thin layer 15 each include at least one kind of impurity metal element except indium. The optical adjustment layer 12 includes a dry-type optical adjustment layer including an inorganic oxide layer.

Both the first transparent conductive thin layer 14 and the second transparent conductive thin layer 15 are crystalline and each include a crystalline structure having an X-ray diffraction peak that corresponds to at least a (400) plane and a (440) plane. When the X-ray diffraction peak intensity of the (400) plane is I₄₀₀ arid the X-ray diffraction peak intensity of the (440) plane is I₄₄₀, the ratio of the X-ray diffraction park intensity I₄₄₀/I₄₀₀ is in a range from 1.0 to 2.2. The first transparent conductive thin layer 14 and the second transparent conductive thin layer 15 further preferably each include a crystalline structure having an X-ray diffraction peak that corresponds to a (222) plane. When the X-ray diffraction peak intensity of the (222) plane is I₂₂₂, the ratio of the X-ray diffraction peak intensity is in a range from 0.10 to 0.26.

The first transparent conductive thin layer 14 and the second transparent conductive thin layer 15 each have a content ratio of impurity metallic element relative to indium of 0.004 or more to 0.16 or less, more preferably 0.01 or more to 0.15 or less, further preferably 0.03 or more to 0.13 or less. When the content ratio of impurity metallic element relative to indium is less than 0.004, there is a possibility that the surface resistance value of the transparent conductive layer may significantly increase. And when the content ratio of impurity metallic element relative to indium is over 0.16, there is a possibility that uniformity of the surface resistance value of the transparent conductive layer may be lost. In the case where indium tin oxide is used as the first transparent conductive thin layer 14 and the second transparent conductive thin layer 15, that is, in the case where such content ratios are represented by tin oxide content ratios (percentage of the weight of SnO₂ relative to the total weight of In₂O₃ and SnO₂) when main metal is indium and the impurity metallic element is tin, the content ratio is substantially 0.5 weight % or more to 15 weight % or less, 1 weight % or more to 15 weight % or less, 3 weight % or more, and 12.5 weight % or less.

The second transparent conductive thin layer 15 more preferably has a content ratio of impurity metallic element of 0.05 or more to 0.16 or less relative to indium, 0.09 or more to 0.13 or less is particularly preferable and 0.09 or more to 0.13 or less is the most preferable. When the content ratio of impurity metallic element relative to indium is in the aforementioned range, it is possible to obtain a transparent conductive thin layer which is superior in low resistivity characteristic. In the case where indium tin oxide is used as the second transparent conductive thin layer 15, that is, in the case where such content ratio is represented by a tin oxide content ratio (percentage of the weight of SnO₂ relative to the total weight of In₂O₃ and SnO₂) when the main metal is indium and the impurity metallic element is tin, the content ratio is substantially 5 weight % or more to 15 weight % or less, 6 weight % or more to 15 weight % or less, 9 weight % or more, and 12.5 weight % or less.

The content ratio of impurity metallic element to indium in the first transparent conductive thin layer 14 is more preferably 0.004 or more to less than 0.05, particularly preferably 0.01 or more to 0.04 or less. When the content ratio of impurity metallic element relative to indium is in the aforementioned range, it is possible to obtain a transparent conductive thin layer with a rapid crystallization speed that can be crystallized by a short period heating treatment (e.g. 140° C., 45 minutes). In the case where indium tin oxide is used as the first transparent conductive thin layer 14, that is, in the case where such content ratios are represented by tin oxide content ratios (percentage of the weight of SnO₂ relative to the total weight of In₂O₃ and SnO₂) when the main metal is indium and the impurity metallic element is tin, the content ratio is substantially 0.5 weight % or more to less than 5 weight %, 1 weight % or more to 4 weight % or less.

For instance, the first transparent conductive thin layer 14 whose content ratio of impurity metallic element relative to indium is 0.04 or more to less than 0.05 is formed on the second transparent conductive thin layer 15 whose content ratio of impurity metallic element relative to indium is 0.05 or more to 0.16 or less. This makes it possible to obtain a transparent conductive layer having a fast crystallization rate and low resistivity as well as it becomes easy to adjust the ratio of the X-ray diffraction peak intensity (I₄₀₀/I₂₂₂ and I₄₄₀/I₄₀₀) of the transparent conductive layer.

The content ratio of impurity metallic element relative to indium in the first transparent conductive thin layer 14 is lower than the content ratio of impurity metallic element relative to indium in the second transparent conductive thin layer 15. Although not illustrated, in the case where the transparent conductive layer is a transparent conductive thin laminate on which at least three layers of transparent conductive thin layers are laminated, the content ratio of impurity metallic element relative to indium in the first transparent conductive thin layer is not the maximum out of content ratios of impurity metallic element relative to indium in all of the transparent conductive thin layers when the transparent conductive thin layer located in a position that is most far from the film substrate is used as the first transparent conductive thin layer. More specifically, a transparent conductive thin layer having a high content ratio of impurity metallic element relative to indium in the first transparent conductive thin layer is separately provided. More preferably, the content ratio of impurity metallic element relative to indium in the first transparent conductive thin layer is the minimum out of all of the content ratios of impurity metallic element relative to indium in all of the transparent conductive thin layers.

While the transparent conductive layer having a low content ratio of impurity metallic element relative to indium has a high resistance value when crystallized, the transparent conductive layer is easy to be crystallized. While the transparent conductive layer having a high content ratio of impurity metallic element relative to indium is not easy to be crystallized, the transparent conductive layer has a low resistance value when crystallized. When the transparent conductive layer is a two-layer structure composed of the first transparent conductive thin layer 14 having a low content ratio of impurity metallic element relative to indium and the second transparent conductive thin layer 15 having a high content ratio of impurity metallic element relative to indium, crystallization of the entire transparent conductive layer is promoted by the first transparent conductive thin layer 14. As a result, a layer having a low resistance value is obtainable by the second transparent conductive thin layer 15 when the entire transparent conductive layer has been crystallized. To make the resistance value lower after the crystallization, it is advantageous that the thickness of the first transparent conductive thin layer 14 is thicker than the thickness of the second transparent conductive thin layer 15. Similarly, when the transparent conductive layer has three layers or more, crystallization of the entire transparent conductive layers is promoted more in the case where the first transparent conductive thin layer has a lower content ratio of impurity metallic element relative to indium than the other transparent conductive thin layers and the thickness of the first transparent conductive thin layer is thinner than the other transparent conductive thin layers. In addition, it is possible to obtain a layer with a low resistance value when the entire transparent conductive layer has been crystallized. The thickness of the first transparent conductive thin layer 14 is e.g. less than 50% of the thickness of the transparent conductive layer (for example, the total thickness of the first transparent conductive thin layer 14 and the second transparent conductive thin layer 15 in the case of a two-layer structure), preferably 45% or less, more preferably 40% or less, furthermore preferably 30% or less.

### EXAMPLES AND COMPARATIVE EXAMPLES

While concrete embodiments of the transparent conductive film of the present invention will now be described in contrast between Examples and Comparative Examples, the present invention is not limited to these Examples. Various modifications and changes can be made based on the technical concept of the present invention.

### Example 1

A transparent conductive film in Example 1 is such layer-structured as shown in FIG. 2. A film substrate is a 100 μm-thick polyethylene terephthalate (PET) film. An optical adjustment layer is composed of a Si oxide layer having a thickness of 20 nm. A first transparent conductive thin layer is composed of a first indium tin oxide (ITO) layer (thickness: 3 nm). A second transparent conductive thin layer is composed of a second indium tin oxide (ITO) layer (thickness: 19 nm). The content ratio (the ratio of number of atoms Sn/In of Sn number of atoms relative to In number of atoms) of tin (impurity metallic element) relative to indium in the first indium tin oxide layer (first transparent conductive thin layer) is 0.03. The content ratio (the ratio of number of atoms Sn/In of Sn number of atoms relative to In number of atoms) of tin (impurity metallic element) relative to indium in the second indium tin oxide layer (second transparent conductive thin layer) is 0.10.

### [Film Substrate]

A 0.3 μm-thick hard coat layer composed of an ultraviolet-curable resin including an acrylic resin was formed on a main surface (a surface of a side where an optical adjustment layer was formed) of a 100 μm-thick polyethylene terephthalate film (produced by Mitsubishi Plastics, Inc.) to be used as a film substrate.

### [Formation of Optical Adjustment Layer]

An optical adjustment layer (and a first transparent conductive thin layer and a second transparent conductive thin layer to be described later) was formed by use of a roll-to-roll sputtering apparatus.

A roll of a film substrate was disposed in a supply part of a sputtering apparatus to be stored for 15 hours in a vacuum state of 1×10⁻⁴ Pa or less. Subsequently, the film substrate was rolled out from the supply part and conveyed while making a back surface of the film substrate (a surface opposite to a surface of the hard coat layer) in contact with a deposition roll with a surface temperature of 0° C. to deposit an optical adjustment layer on the film substrate (on the hard coat layer). The optical adjustment layer is a silicon oxide layer with a thickness of 20 nm in total including a silicon oxide (SiOx (x=1.5)) layer with a thickness of 3 nm and a dioxide silicon (SiO₂) layer with a thickness of 17 nm formed on the silicon oxide layer. When the thus obtained silicon oxide layer was evaluated with a layer density by the X-ray reflectivity, the layer density was 2.2 g/cm³.

The silicon oxide (SiOx (x=1.5) layer was formed on a film substrate (a hard coat layer) by sputtering a Si target (produced by Sumitomo Metal Mining Co., Ltd.) under a vacuum atmosphere of 0.2 Pa where argon and oxygen (flow ratio of argon:oxygen=100:38) introduced by use of alternating-current/medium frequency (AC/MF) power supply. The dioxide silicon (SiO₂) layer was formed on the silicon oxide (Siox (x=1.5) layer by sputtering a Si target (produced by Sumitomo Metal Mining Co., Ltd.) under a vacuum atmosphere of 0.3 Pa where argon and oxygen (flow ratio of argon:oxygen=100:1) introduced by use of alternating-current/medium frequency (AC/MF) power supply.

### [Formation of Transparent Conductive Layer]

Subsequent to the optical adjustment layer, a transparent conductive layer was formed. The transparent conductive layer was a transparent conductive thin layer laminate composed of a two-layer structure of a second transparent conductive thin layer and a first transparent conductive thin layer. A back side (a side opposite to the optical adjustment layer) of the film substrate on which the optical adjustment layer was formed was conveyed while making the back side of the film substrate in contact with a layer forming roll having a surface temperature of 0° C. to form a second transparent conductive thin layer having a thickness of 19 nm (tin/indium content ratio Sn/In=0.10) on the optical adjustment layer. Subsequently, a first transparent conductive thin layer having a thickness of 3 nm (tin/indium content ratio Sn/In=0.03) was formed on the second transparent conductive thin layer.

The second transparent conductive thin layer was formed by sputtering an indium tin oxide target composed of an indium oxide sintered body which includes 10 weight % of tin oxide and 90 weight % of indium oxide under a vacuum atmosphere of 0.4 Pa where argon and oxygen (flow ratio of argon:oxygen=99:1) introduced by use of a horizontal magnetic field with 30 mT and an direct-current (DC) power supply.

The first transparent conductive thin layer was formed by sputtering an indium tin oxide target composed of an indium oxide sintered body which includes 3 weight % of tin oxide and 97 weight % of indium oxide under a vacuum atmosphere of 0.4 Pa where argon and oxygen (flow ratio of argon:oxygen=99:1) introduced by use of a horizontal magnetic field with 30 mT and a direct-current (DC) power supply. In this way, an amorphous transparent conductive layer where the first transparent conductive thin layer and the second transparent conductive thin layer are laminated. And then crystallization treatment was done by heating at 140° C. for 90 minutes under atmosphere to produce a transparent conductive film in Example 1 including a crystalline transparent conductive layer.

### Example 2

A transparent conductive film in Example 2 was produced in the same manner as in Example 1 except that a first indium tin oxide layer (a first transparent conductive thin layer) was set to have a thickness of 6 nm and a second indium tin oxide layer (a second transparent conductive thin layer) was set to have a thickness of 16 nm.

### Example 3

A transparent conductive film in Example 3 was produced in the same manner as in Example 1 except that a first indium tin oxide layer (a first transparent conductive thin layer) was set to have a thickness of 8 nm and a second indium tin oxide layer (a second transparent conductive thin layer) was set to have a thickness of 14 nm.

### Example 4

A transparent conductive film in Example 4 was produced in the same manner as in Example 1 except that a first indium tin oxide layer (a first transparent conductive thin layer) was set to have a thickness of 4 nm and a second indium tin oxide layer (a second transparent conductive thin layer) was set to have a thickness of 18 nm.

### Example 5

A transparent conductive film in Example 5 was produced in the same manner as in Example 1 except that a first indium tin oxide layer (a first transparent conductive thin layer) and a second indium tin oxide layer (a second transparent conductive thin layer) were formed by use of a magnet of a horizontal magnetic field with 100 mT. The specific resistance value of a transparent conductive layer becomes lower by increasing the horizontal magnetic field from 30 mT to 100 mT.

### Comparative Example 1

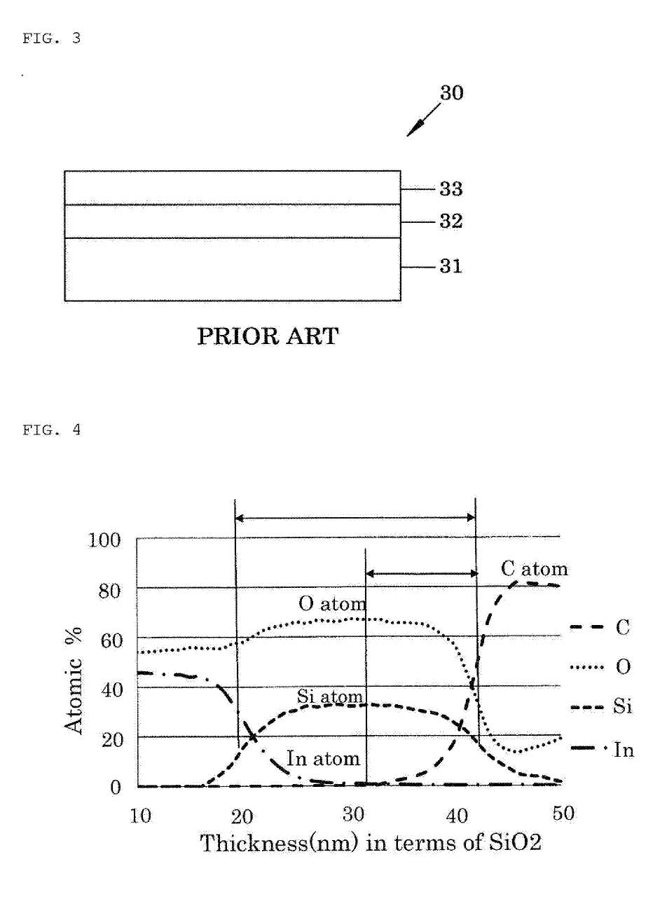

FIG. 3 shows the layer configuration of a transparent conductive film in Comparative Example 1. In Comparative Example 1, an optical adjustment layer is a wet-type optical adjustment layer. A thermosetting resin composed of a mixture of a melamine resin, an alkyd resin, and organic silane condensate (weight ratio of melamine resin:alkyd resin:organic silane condensate:2:2:1) was dissolved in an organic solvent and was coated with a film substrate to be thermoset. As a result, a wet-type optical adjustment layer was formed. The wet-type optical adjustment layer had a thickness of 35 nm. The transparent conductive layer was composed of two layers; a first indium tin oxide layer and a second indium tin oxide layer. The transparent conductive film in Comparative Example 1 was produced in the same manner as in Example 1 except that the first indium tin oxide layer was set to have a thickness of 4 nm and the second indium tin oxide layer was set to have a thickness of 18 nm in the formation method thereof.

### Comparative Example 2

In a transparent conductive film in Comparative Example 2, an indium tin oxide layer is one-layer and the layer configuration thereof is the same as that in FIG. 1. An indium tin oxide layer (content ratio of indium/tin:Sn/In=0.08) with a thickness of 21 nm was produced by sputtering an indium tin oxide target composed of an indium oxide sintered body which includes 8 weight % of tin oxide and 92 weight % of indium oxide under a vacuum atmosphere of 0.3 Pa where argon and oxygen (flow ratio of argon:oxygen=99:1) were introduced. A transparent conductive film in Comparative Example 2 was produced in the same manner as in Example 1 except the above.

### Comparative Example 3

In a transparent conductive film in Comparative Example 3, an indium tin oxide layer is one-layer and the layer configuration of the layer thereof is the same as that in FIG. 1. An indium tin oxide layer (content ratio of indium/tin:Sn/In=0.07) with a thickness of 22 nm was produced by sputtering an indium tin oxide target composed of an indium oxide sintered body which includes 7 weight % of tin oxide and 93 weight % of indium oxide under a vacuum atmosphere of 0.3 Pa where argon and oxygen (flow ratio of argon:oxygen=99:1) were introduced. The transparent conductive film in Comparative Example 3 was produced in the same manner as in Example 1 except for the above.

Table 1 shows the configuration and characteristics of transparent conductive films in Examples 1 to 5 and Comparative Examples 1 to 3 of the present invention. In addition, while there is no description in Table 1, it was confirmed that specific resistance values of transparent conductive layers in transparent conductive films in Examples 1 to 5 and Comparative Examples 1 to 3 are in a range from 3.2×10⁻⁴ Ω·cm to 3.6×10⁻⁴ Ω·cm in Examples 1 to 4 and Comparative Examples 1-3 and the specific resistance value of the transparent conductive layer in the transparent conductive film in Example 5 was 2.2×10⁻⁴ Ω·cm. Since the transparent conductive layers in the transparent conductive films in Examples 1 to 5 and Comparative Examples 1 to 3 are crystalline, specific resistance values in the aforementioned range are obtained. In the case of the aforementioned specific resistance values, thus obtained transparent conductive films can preferably be used for touch panels or the like.

TABLE 1

| | | | Thickness | | | | | | | | |
|---|---|---|---|---|---|---|---|---|---|---|---|
| | | | of transparent | | Content ratio of (Sn/In) | | | | | | |
| | | Percentage | conductive layer | | of tin in an indium | | | | | | |
| | Thick- | of an area in | First | Second | tin oxide layer | | | | | | |
| | ness | which | transparent | transparent | First | Second | | | | | |
| | of | carbon atom | conductive | conductive | transparent | transparent | | | | | |
| | optical | in an optical | thin layer | thin layer | conductive | conductive | | | | | Mechan- |
| | adjust- | adjustment | (first indium | (second | thin layer | thin layer | | | | | ical |
| | ment | layer is not | tin oxide | indium tin | (first indium | (second | Etching time | | X-ray diffraction | | property |
| | layer | more than | layer) | oxide layer) | tin oxide | indium tin | Sec- | Judg- | peak ratio | | Scratch |
| | nm | 0.2 atomic % | nm | nm | layer) | oxide layer) | onds | ment | I₄₀₀/I₂₂₂ | I₄₄₀/I₄₀₀ | resistance |
| Example 1 | 20 | 50% or more | 3 | 19 | 0.03 | 0.10 | 90 | Good | 0.16 | 1.44 | Good |
| Example 2 | 20 | 50% or more | 6 | 16 | 0.03 | 0.10 | 100 | Good | 0.18 | 1.64 | Good |
| Example 3 | 20 | 50% or more | 8 | 14 | 0.03 | 0.10 | 100 | Good | 0.21 | 1.31 | Good |
| Example 4 | 20 | 50% or more | 4 | 18 | 0.03 | 0.10 | 90 | Good | 0.20 | 1.34 | Good |
| Example 5 | 20 | 50% or more | 3 | 19 | 0.03 | 0.10 | 100 | Good | 0.15 | 1.55 | Good |
| Comparative | 35 | N/L | 4 | 18 | 0.03 | 0.10 | 60 | Good | 0.06 | 3.50 | Bad |
| Example 1 | | | | | | | | | | | |
| Comparative | 20 | 50% or more | 21 | — | 0.08 | — | 120 | Bad | 0.09 | 2.32 | Good |
| Example 2 | | | | | | | | | | | |
| Comparative | 20 | 50% or more | 22 | — | 0.07 | — | 130 | Bad | 0.27 | 0.91 | Good |
| Example 3 | | | | | | | | | | | |

### [Content of Carbon Atom]

It was confirmed by an Electron Spectroscopy for Chemical Analysis (ESCA) that optical adjustment layers (a silicon oxide layer with a thickness of 20 nm formed by the sputtering method) in Examples 1 to 5 and Comparative Examples 2 and 3 each have an area of 0.2 atomic % or less where there was at least 50% or more of a carbon atom in a thickness direction. And it was confirmed by the Electron Spectroscopy for Chemical Analysis that there was no area where carbon atom was 0.2 atomic % or less in a thickness direction in the wet-type optical adjustment layer (a thermosetting resin layer with thickness of 35 nm formed by coating in Comparative Example 1).

### [Etching Time]

Etching rates of transparent conductive layers in Examples and Comparative Examples were measured for time that had taken to lose substantial conductivity of the transparent conductive layers (Resistance between two terminals is over 60 MΩ). In etching test conditions of this specification (to be described later) in the present invention, the case where etching time is 110 seconds or shorter was judged as “good” and the case where etching time was over 110 seconds was judged as “bad.”

Etching time of a transparent conductive layer with a wet-type optical adjustment layer in Comparative Example 1 was 60 seconds. Etching time of transparent conductive layers each having a dry-type optical adjustment layer in Comparative Examples 1 to 5 was 90 seconds to 100 seconds. While the etching time of the transparent conductive layers in Example 1 to 5 was longer than the etching time of the transparent conductive layer in Comparative Example 1, the etching time was in the level of acceptable (Good) because of being 110 seconds or shorter. The etching time of the transparent conductive layers in Comparative Examples 2 to 3 was 120 seconds to 130 seconds, which was in the level of unacceptable (Bad).

Although it is not described in Table 1 because of being a reference example, a transparent conductive film with crystalline transparent conductive layers in a reference example was produced in the same manner as in Comparative Example 1 except that a first indium tin oxide layer (first transparent conductive thin layer) and a second indium tin oxide layer (second transparent conductive thin layer) were formed by use of a magnet with a horizontal magnetic field of 100 mT. Subsequently, evaluations of specific resistance, etching time, and scratch resistance were carried out with reference to the transparent conductive film in the reference example in the same manner as in Examples and Comparative Examples. As a result, the specific resistance value was 2.1×10⁻⁴ Ω·cm and the etching time was 90 seconds, and the scratch resistance was judged as “unacceptable.”

In comparison between Comparative Example 1 with a wet-type optical adjustment layer and the reference example, when compared with Comparative Example 1, the reference example had a lower specific resistance value than Comparative Example 1 (specifically, while the specific resistance value of Comparative Example 1 is 3.2×10⁻⁴ Ω·cm to 3.6×10⁻⁴ Ω·cm, the specific resistance value of the reference example is 2.1×10⁻⁴ Ω·cm). The etching time of the reference example is, however, longer (specifically, while the etching time of the Comparative Example 1 is 60 seconds, the etching time of the reference example is 90 seconds). As mentioned above, in a transparent conductive film with a wet-type optical adjustment layer, there is a also a tendency of longer etching time when making the specific resistance value of the transparent conductive layer lower. In a transparent conductive film with a dry-type optical adjustment layer, such a tendency is more prominent than the transparent conductive film with a wet-type optical adjustment layer.

In the transparent conductive film of the present invention, crystalline orientation of the transparent conductive layer is controlled and X-ray diffraction peak intensities that correspond to the (400) plane, the (440) plane or the (222) plane are adjusted to a preferable level. This leads to realize a preferable etching rate (100 seconds) like Example 5, even when the transparent conductive layer having a low specific resistance (e.g. 2.2×10⁻⁴ Ω·cm) is used.

### [X-ray Diffraction Peak Ratio and Etching Time]

X-ray diffraction peak intensity of a (222) plane of a transparent conductive layer was set at I₂₂₂, X-ray diffraction peak intensity of a (400) plane of the transparent conductive layer was set at I₄₀₀, and X-ray diffraction peak intensity of a (440) plane of the transparent conductive layer was set at I₄₄₀. With reference to the ratio of the X-ray diffraction peak intensity, Example 1 was 0.16, Example 2 was 0.13, Example 3 was 0.21, Example 4 was 0.20, and Example 5 was 0.15, which were all in a range from 0.10 to 0.26. On the other hand, Comparative Example 1 was 0.06, Comparative Example 2 was 0.09, and Comparative Example 3 was 0.27, which were not in the range of 0.10 to 0.26, either.

Next, with reference to the ratio of the X-ray diffraction peak intensity I₄₄₀/I₄₀₀, Example 1 was 1.44, Example 2 was 1.64, Example 3 was 1.31, Example 4 was 1.34, and Example 5 was 1.55, which were all in a range from 1.0 to 2.2. On the other hand, Comparative Example 1 was 3.50, Comparative Example 2 was 2.32, and Comparative Example 3 was 0.91, which were not in the range of 1.0 to 2.2, either.

As a result, at least when the ratio of the x-ray diffraction peak intensity I₄₄₀/I₄₀₀ was in the range of 1.0 to 2.2, it turned out that etching time (etching rate) was in a preferable range. Further, the ratio of the X-ray diffraction peak intensity I₄₀₀/I₂₂₂ was more preferably in a range from 0.10 to 0.26. Generally, when etching time (etching rate) is in a preferable range, etching accuracy can be maintained high.

### [Scratch Resistance]

Since optical adjustment layers in Examples 1 to 5, Comparative Examples 2 and 3 each include a dry-type optical adjustment layer, there were no problems with scratch resistance (Good). On the other hand, since an optical adjustment layer in Comparative Example 1 included a wet-type optical adjustment layer, scratch resistance thereof was low (Bad).

### [Measuring Method]

### [Layer Thickness]

The thickness of the film substrate was measured by using a thickness meter (manufactured by OZAKI MFG. CO., LTD. (Peacock registered trademark); apparatus name “Digital Dial Gauge DG-205). The thickness of each of the hard coat layer, the optical adjustment layer and the transparent conductive layer was measured by observing a cross-section using a transmission electron microscope (manufactured by Hitachi, LTD.; apparatus name “HF-2000”).

### [Specific Resistance Value]

A surface resistance value of each of the transparent conductive films in Examples and Comparative Examples was measured by using the four terminal method in accordance with the JIS K7194. Subsequently, the measured surface resistance value and the thickness of the transparent conductive layer obtained by the method described in the aforementioned item of [layer thickness] were used to calculate a specific resistance value.

### [Etching Time]

Transparent conductive films in Examples and Comparative Examples were each cut into a square sheet having an angle of 5 cm to be immersed in 10 weight % of hydrochloric acid which was adjusted to the temperature at 50° C. Such a square sheet was each taken out every 10 seconds for dipping time to perform cleaning by water and wiping of water (drying). Resistance between two terminals at any three points were measured with tester. In addition, a distance between terminals when measuring a resistance between two terminals was set at 1.5 cm. And then etching was judged to be completed at the point that resistance between two terminals measured in any three points had been over 60 MΩ. Time that required for the completion of etching was etching time.

### [Content of Carbon Atom of Optical Adjustment Layer and Evaluation of Existence Area]

Evaluation of an existence area in a thickness direction of carbon atoms of an optical adjustment layer was carried out by the Electron Spectroscopy for Chemical Analysis (ESCA) by use of a measuring device Quantum 2000 (manufactured by ULVAC-PHI).

FIG. 4 shows one example of a profile of the Electron Spectoscopy for Chemical Analysis. A depth profiling measurement on each element for indium In, silicon Si, and oxygen O, carbon C was performed while etching a transparent conductive layer with argon Ar ions toward a film substrate direction from a side of the transparent conductive layer of a transparent conductive film to calculate atomic % of the aforementioned four elements per 1 nm in silicon dioxide (SiO₂) equivalent. The existence area in a thickness direction of impurity atoms (carbon atoms) was obtained by an equation (T₂/T₁)×100(%) from a layer thickness T₁ of SiO₂ layer and a layer thickness T₂ of an area where carbon atoms were detected.

A method for obtaining a layer thickness T₁ of a silicon oxide layer will be described below. FIG. 4 shows a depth profile for the aforementioned four elements measured in silicon dioxide (SiO₂) equivalent per 1 nm. A horizontal axis indicates a thickness direction (nm). A vertical axis indicates atomic %. In FIG. 4, a left end is a transparent conductive layer side (surface side) and a right end is a film substrate side. In the Electron Spectroscopy for Chemical Analysis, while a depth profile in thickness expand from the nature of the analysis, in the layer thickness T₁ of a silicon oxide layer, a position where atomic % of silicon Si was reduced to half on the surface side was referred to as an outermost portion of the silicon oxide layer and a position where atomic % of silicon Si was reduced to half on the film substrate side was referred to as a deepest portion of the silicon oxide layer relative to a maximum value of the atomic % of silicon Si, and the thickness there between was referred to as the layer thickness T₁ of the silicon oxide layer.

In addition to obtaining the layer thicknesses T₁ in such a manner, a thickness T₂ of an area where carbon atoms have been detected as impurity atoms was calculated to obtain an existence area of the impurity atoms (T₂/T₁)×100(%). An area where the content of carbon atoms was 0.2 atomic % or less was calculated by an equation “100−(T₂/T₁)×100(%).”

### [X-ray Diffraction Peak Ratio]

An X-ray diffraction peak of a transparent conductive layer in a transparent conductive film in each Example and Comparative Example was obtained by measuring X-ray diffraction by use of a horizontal x-ray diffraction system SmartLab (manufactured by Rigaku Corporation). Further, measurement was carried out as per conditions below to set each peak intensity at a value from which a background was deducted. As mentioned above, X-ray diffraction peak intensities I₂₂₂, I₄₀₀, and I₄₄₀ which correspond to the (222) plane, the (400) plane, and the (440) plane were obtained. As a result, I₄₄₀/I₄₀₀ and I₄₀₀/I₂₂₂ were obtained.
Parallel beam optical arrangement
Light source: ChK α line (wavelength: 1.54186 amp.)
Output: 45 KV, 20 mA
Incident side slit-base: Solar slit 5.0°
Height control slit: 10 mm
Incident slit: 0.1 mm
Receiving light-side slit: Parallel slit analyzer (PSA) 0.114 deg.
Detector: Scintillation counter
Sample stage: A general holder was used to fix samples by suction with a pump.
X-ray incident angle: 0.50° (in the case where sufficient intensity is not obtained, incident angles were measured at 0.40°, 0.45°, 0.55°, and 0.60° respectively and results in which targeted peaks were the intensest were adopted).
Step intervals: 0.01°
Measuring rate: 3.0°/minute
Measurement range 10° to 60°

### [Scratch Resistance]

A transparent conductive film in each Example and Comparative Example was cut in the form of a rectangle of 5 cm×11 cm. A silver paste was applied to both end parts of 5 mm on a long edge side and was naturally dried for 48 hours. Subsequently, a side of the transparent conductive film, which was an opposite side to the transparent conductive adhesive to obtain a sample for evaluation of scratch resistance.

At a central position (a position of 2.5 cm) on a short edge side of the sample for evaluation of scratch resistance, the surface of the transparent conductive layer in the sample for evaluation of scratch resistance was rubbed over a length of 10 cm in a long side direction under the following conditions using a decuplet-type pen testing machine (manufactured by MTM Company). A resistance value (R0) of the sample for evaluation of scratch resistance before the sample was rubbed and a resistance value (R20) of the sample for evaluation of scratch resistance after the sample was rubbed were measured by putting a tester on the silver paste part on both end parts at a central position (a position of 5.5 cm) on the long edge side of the sample for evaluation of scratch resistance. A resistance change ratio (R20/R0) was obtained to evaluate scratch resistance. A sample having a resistance change ratio of 1.5 or less was rated “Good,” and a sample having a resistance change ratio over 1.5 was rated “Bad.”
Scratcher: ANTICON GOLD (manufactured by CONTEC CO., LTD.)
Load: 127 g/cm²
Scratch rate: 13 cm/second (7.8 m/minute)
Scratch number: 20 (10 rounds)

### INDUSTRIAL APPLICABILITY

While the uses of the transparent conductive film of the present invention are not limited, in particular, the transparent conductive film of the present invention is preferably used for a touch panel.

1. A transparent conductive film comprising:
a transparent film substrate;
an optical adjustment layer; and
a transparent conductive layer,
at least the optical adjustment layer and the transparent conductive layer being laminated on at least one main surface of the transparent film substrate,
the optical adjustment layer includes a dry-type optical adjustment layer including an inorganic oxide,
the transparent conductive layer includes a metal oxide including indium,
the transparent conductive layer is crystalline and has an X-ray diffraction peak respectively at least on a (400) plane and a (440) plane, and
when the (400) plane has an X-ray diffraction peak intensity of I₄₀₀ and the (440) plane has an X-ray diffraction peak intensity of I₄₄₀, a ratio I₄₄₀/I₄₀₀ of the X-ray diffraction peak intensity is in a range from 1.0 to 2.2.

2. A transparent conductive film comprising:
a transparent film substrate;
an optical adjustment layer; and
a transparent conductive layer,
at least the optical adjustment layer and the transparent conductive layer being laminated on at least one main surface of the transparent film substrate,
the optical adjustment layer includes a dry-type optical adjustment layer including an inorganic oxide,
the transparent conductive layer includes a metal oxide including indium,
the transparent conductive layer is crystalline and has an X-ray diffraction peak respectively at least on a (222) plane, a (400) plane, and a (440) plane, and
when the (222) plane has an X-ray diffraction peak intensity of I₂₂₂, the (400) plane has an X-ray diffraction peak intensity of I₄₀₀, and the (440) plane has an X-ray diffraction peak intensity of I₄₄₀, a ratio I₄₀₀/I₂₂₂ of the X-ray diffraction peak intensity is in a range from 0.10 to 0.26 and a ratio I₄₄₀/I₄₀₀ of the X-ray diffraction peak intensity is in a range of 1.0 to 2.2.

3. (canceled)

4. (canceled)

5. (canceled)

6. (canceled)

7. (canceled)

8. (canceled)

9. (canceled)

10. The transparent conductive film according to claim 1, wherein the dry-type optical adjustment layer includes an area of an inorganic oxide having a carbon atom content of 0.2 atomic % or lower in a thickness direction.

11. The transparent conductive film according to claim 2, wherein the dry-type optical adjustment layer includes an area of an inorganic oxide having a carbon atom content of 0.2 atomic % or lower in a thickness direction.

12. The transparent conductive film according to claim 1, wherein the transparent conductive layer is a transparent conductive thin layer laminate composed of at least two layers of transparent conductive thin layers,
all of the transparent conductive thin layers include at least one kind of impurity metallic element except indium, and
when a transparent conductive thin layer located at a position that is the farthest from the film substrate is a first transparent conductive thin layer, the content ratio of impurity metallic element relative to indium in the first transparent conductive thin layer is not the maximum out of content ratios of impurity metallic element relative to indium in all of the transparent conductive thin layers that constitute the transparent conductive thin layer laminate.

13. The transparent conductive film according to claim 2, wherein the transparent conductive layer is a transparent conductive thin layer laminate composed of at least two layers of transparent conductive thin layers,
all of the transparent conductive thin layers include at least one kind of impurity metallic element except indium, and
when a transparent conductive thin layer located at a position that is the farthest from the film substrate is a first transparent conductive thin layer, the content ratio of impurity metallic element relative to indium in the first transparent conductive thin layer is not the maximum out of content ratios of impurity metallic element relative to indium in all of the transparent conductive thin layers that constitute the transparent conductive thin layer laminate.

14. The transparent conductive film according to claim 12, wherein the content ratio of impurity metallic element relative to indium in the first transparent conductive thin layer is the lowest out of the content ratios of impurity metallic element relative to indium in all of the transparent conductive thin layers that constitute the transparent conductive thin layer laminate.

15. The transparent conductive film according to claim 13, wherein the content ratio of impurity metallic element relative to indium in the first transparent conductive thin layer is the lowest out of the content ratios of impurity metallic element relative to indium in all of the transparent conductive thin layers that constitute the transparent conductive thin layer laminate.

16. The transparent conductive film according to claim 12, wherein the content ratio of impurity metallic element relative to indium in the first transparent conductive thin layer is 0.004 or more to less than 0.05.

17. The transparent conductive film according to claim 13, wherein the content ratio of impurity metallic element relative to indium in the first transparent conductive thin layer is 0.004 or more to less than 0.05.

18. The transparent conductive film according to claim 12, wherein a content ratio of impurity metallic element relative to indium in each transparent conductive thin layer except the first transparent conductive thin layer is 0.05 or more to 0.16 or less.

19. The transparent conductive film according to claim 13, wherein a content ratio of impurity metallic element relative to indium in each transparent conductive thin layer except the first transparent conductive thin layer is 0.05 or more to 0.16 or less.

20. The transparent conductive film according to claim 12, wherein the first transparent conductive thin layer has a thickness thinner than the thickness of all of the other transparent conductive thin layers except the first transparent conductive thin layer in the at least two layers of transparent conductive thin layers that constitute the transparent conductive thin layer laminate.

21. The transparent conductive film according to claim 13, wherein the first transparent conductive thin layer has a thickness thinner than the thickness of all of the other transparent conductive thin layers except the first transparent conductive thin layer in the at least two layers of transparent conductive thin layers that constitute the transparent conductive thin layer laminate.

22. The transparent conductive film according to claim 12, wherein the impurity metallic element is composed of tin (Sn).

23. The transparent conductive film according to claim 13, wherein the impurity metallic element is composed of tin (Sn).
